(19) United States
(12) Patent Application Publication
(10) Pub. No.: US 2007/0011591 A1
(43) Pub. Date: Jan. 11, 2007

(54) METHOD FOR GENERATING SYNDROME VALUE AND APPARATUS THEREOF

(76) Inventors: Li-Lien Lin, Hsin-Chu City (TW); Pi-Hai Liu, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/421,484

(22) Filed: Jun. 1, 2006

(30) Foreign Application Priority Data
Jun. 17, 2005 (TW) 094120231

(51) Int. Cl. H03M 13/00

(52) U.S. Cl. 714/785

(57) ABSTRACT

The present invention discloses a method for generating a syndrome value of an error correction codeword (ECC), and a related apparatus. The ECC includes a fixed section, an information section, and a parity section. The fixed section includes not only byte “00”. The method provides a fixed syndrome value according to characteristics of the ECC. The syndrome value corresponding to the ECC is generated according to the fixed syndrome value, the information section, and the parity section.

### BACKGROUND

The embodiments relate to error correction codeword (ECC), and more particularly, to a method and apparatus for efficiently generating a syndrome value corresponding to an ECC through providing a fixed syndrome value according to characteristics of the ECC.

In digital data communication and digital data recording, error correction coding is a technique that can be utilized to prevent data errors. Before transmitting or recording digital data, the data is usually encoded as error correction codewords (ECCs). After an ECC is received or retrieved, mathematical operations are performed on the ECC to generate a syndrome value corresponding to the ECC. Then, according to the generated syndrome value, error location(s) and error value(s) in the ECC can be easily determined. The ECC is corrected according to the determined error location(s) and error value(s) to generate the original digital data.

Reed-Solomon codeword is a kind of widely applied error correction codeword. Taking Blu-ray discs as an example, RS (248, 216, 33) codes are utilized to ensure that BCA data and AUX data retrieved from Blu-ray discs are correct. FIG. 1 shows the error correction format of BCA data utilized by Blu-ray discs. In Blu-ray discs, 16 bytes of BCA data and 200 dummy bytes are encoded into a 248 bytes long-distance ECC. The long-distance ECC therefore comprises a fixed section, an information section, and a parity section. The fixed section comprises 200 bytes of “FF”, which are referred to as dummy bytes and are not recorded on Blu-ray discs. The information section comprises 16 information bytes, i.e. the above-mentioned 16 bytes by BCA data. The parity section comprises 32 parity bytes. The last 16 parity bytes of the parity section are not recorded on Blu-ray discs. During the decoding process the last 16 parity bytes of the parity section are marked as erasures.

FIG. 2 shows the error correction format of AUX data utilized by Blu-ray discs. In Blu-ray discs, 112 bytes of AUX data and 104 dummy bytes are encoded into a 248 bytes long-distance ECC. The long-distance ECC therefore comprises a fixed section, an information section, and a parity section. The fixed section comprises 104 bytes of “FF”, which are referred to as dummy bytes and are not recorded on Blu-ray discs. The information section comprises 112 information bytes, i.e. the above-mentioned 112 bytes of AUX data. The parity section comprises 32 parity bytes.

FIG. 3 shows an apparatus of the related art for generating syndrome values corresponding to long-distance ECCs of BCA data and AUX data. The apparatus comprises a multiplexer 310 and a syndrome generator 320. The syndrome generator 320 comprises 32 syndrome byte generators 325. Each of the syndrome byte generators 325 comprises an adder 326 for performing Exclusive OR (XOR) operations, a buffer 327 for buffering a syndrome byte, and a multiplier 328.

For BCA data, the term R(X) shown in FIG. 3 includes the information section and the parity section of a long-distance ECC utilized by Blu-ray discs. The multiplexer 310 sequentially feeds 200 bytes of “FF” and the 48-byte-long R(X) into the syndrome generator 320; the syndrome generator 320 generates the syndrome value corresponding to the long-distance ECC according to the 248-byte-long data received from the multiplexer 310. Roughly speaking, 248 clock cycles are required for generating the syndrome value corresponding to the long-distance ECC.

For AUX data, the term R(X) shown in FIG. 3 includes the information section and the parity section of a long-distance ECC retrieved from a Blu-ray disc. In other words, R(X) includes 112 information bytes and 32 parity bytes. The multiplexer 310 sequentially feeds 104 bytes of “FF” and the 144-byte-long R(X) into the syndrome generator 320; and the syndrome generator 320 generates the syndrome value corresponding to the long-distance ECC according to the 248-byte-long data received from the multiplexer 310. Roughly speaking, 248 clock cycles are required for generating the syndrome value corresponding to the long-distance ECC.

Although there are plenty of dummy bytes included in a long-distance ECC of BCA data and AUX data, while the actual retrieved data constitute only part of the long-distance ECC, related art apparatus still have to generate the syndrome value according to the whole 248-byte-long long-distance ECC. Roughly speaking, 248 clock cycles are consumed for generating the syndrome value. In other words, the method utilized by the related art is not an efficient method for generating syndrome values swiftly.

### SUMMARY

A method for generating a syndrome value corresponding to an error correction codeword (ECC) is disclosed. The ECC comprises a fixed section, an information section, and a parity section. The fixed section includes not only byte “00”. The method comprises providing a fixed syndrome value according to characteristics of the ECC, and generating the syndrome value corresponding to the ECC according to the fixed syndrome value, the information section, and the parity section.

An apparatus for generating a syndrome value corresponding to an error correction codeword (ECC) is disclosed. The ECC comprises a fixed section, an information section, and a parity section. The fixed section includes not only byte “00”. The apparatus comprises a syndrome-providing module and a calculator. The syndrome-providing module provides a fixed syndrome value according to characteristics of the ECC. The calculator, which is coupled to the syndrome-providing module, generates the syndrome value corresponding to the ECC according to the fixed syndrome value, the information section, and the parity section.

A method for generating a syndrome value corresponding to an error correction codeword (ECC) is disclosed. The ECC comprises a fixed section, an information section, and a parity section. The fixed section includes not only byte “00”. The method comprises generating a second modified section according to the information section, the parity section, and a preset section; generating a syndrome value corresponding to the second modified section; and modifying the syndrome value corresponding to the second modified section according to characteristics of the ECC to generate the syndrome value corresponding to the ECC.

An apparatus for generating a syndrome value corresponding to an error correction codeword (ECC) is disclosed. The ECC comprises a fixed section, an information section, and a parity section. The fixed section includes not only byte “00”. The apparatus comprises a revise module, a syndrome generator, and a correction unit. The revise module generates a second modified section according to the information section, the parity section, and a preset section. The syndrome generator, which is coupled to the revise module, generates a syndrome value corresponding to the second modified section. The correction unit, which is coupled to the syndrome generator, inverts a k^{th} syndrome byte of the syndrome value corresponding the second modified section to generate the syndrome value corresponding to the ECC.

### BRIEF DESCRIPTION OF THE DRAWINGS

FIG. 1 shows the error correction format of BCA data utilized by Blu-ray discs.

FIG. 2 shows the error correction format of AUX data utilized by Blu-ray discs.

FIG. 3 shows an apparatus of the related art for generating syndrome values.

FIG. 4, FIG. 5, FIG. 6, and FIG. 7 show apparatuses for generating syndrome values according to various embodiments.

### DETAILED DESCRIPTION

In practice, some kinds of ECC have special characteristics. By taking advantage of the characteristics, syndrome values of these kinds of ECC can be determined more efficiently than in the related art.

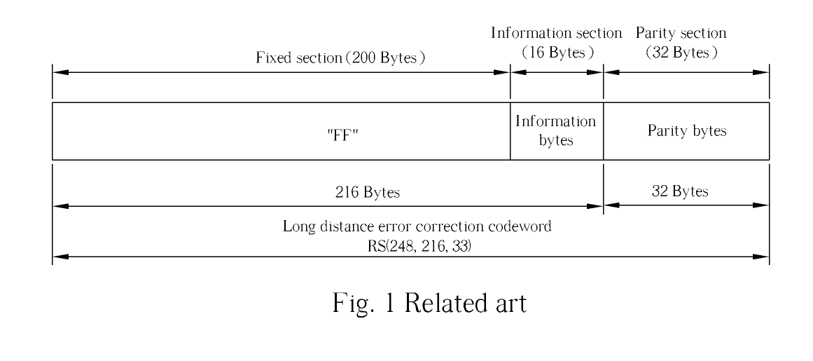

ECCs of BCA data of Blu-ray discs are herein taken as an example. Every ECC comprises a fixed section, an information section, and a parity section. As shown in FIG. 1, the characteristics of the ECC comprise: the fixed section including 200 bytes of “FF,” the information section including 16 information bytes, and the parity section including 32 parity bytes. Hereinafter a term BCA(X) is used to represent an ECC of BCA data, wherein BCA(X)={FF₂₀₀(X), R(X)}, FF₂₀₀(X) represents 200 bytes of “FF”, and R(X) represents the information section and parity section and comprises 16 information bytes and 32 parity bytes. By performing an Exclusive OR operation on BCA(X) and FF₂₄₈(X), the following equations can be obtained:
BCA(X)⊕FF₂₄₈(X)={FF₂₀₀(X), R(X)}⊕FF₂₄₈(X)={00₂₀₀(X), R′(X)}=R′(X)
→BCA(X)=R′(X)⊕FF₂₄₈(X)
→S(BCA(X))=S(R′(X))⊕S(FF₂₄₈(X))

where 00₂₀₀(X) represents 200 bytes of “00”, R′(X) represents the inverted data of R(X), and S(BCA(X)), S(R′(X)), and S(FF₂₄₈(X)) represent syndrome values corresponding to BCA(X), R′(X), and FF₂₄₈(X), respectively.

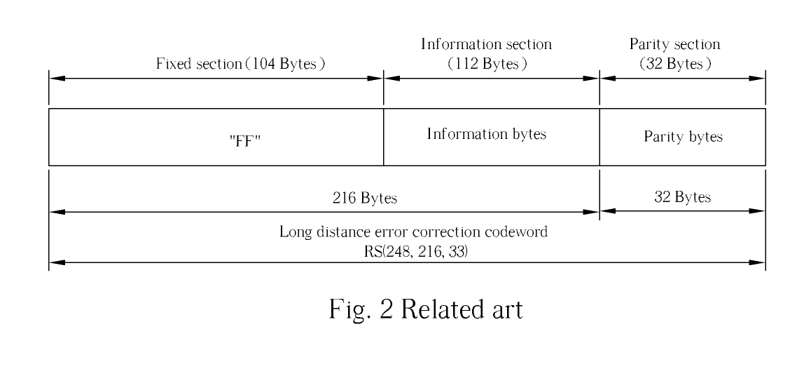

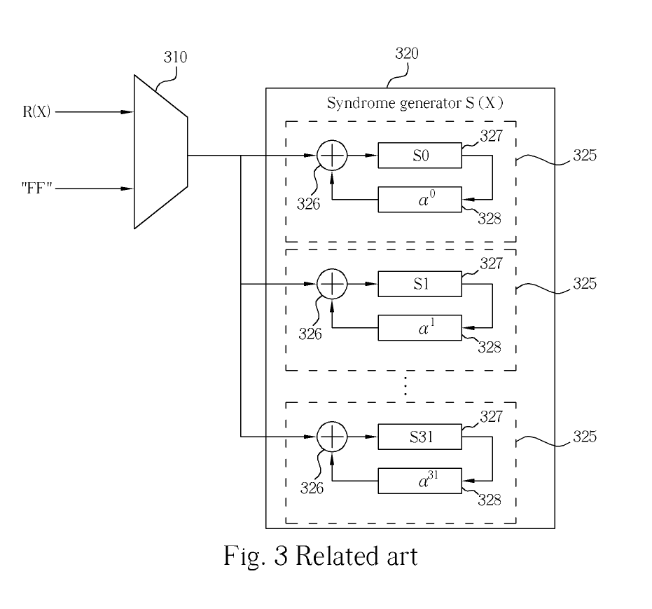

ECCs of AUX data of Blu-ray discs are herein taken as an example. Every ECC comprises a fixed section, an information section, and a parity section. As shown in FIG. 2, the characteristics of the ECC comprise: the fixed section including 104 bytes of “FF,” the information section including 112 information bytes, and the parity section including 32 parity bytes. Hereinafter a term AUX(X) is used to represent an ECC of AUX data, wherein AUX(X)={FF₁₀₄(X), R(X)}, FF₁₀₄(X) represents 104 bytes of “FF”, and R(X) represents the information section and parity section and comprises 112 information bytes and 32 parity bytes. By performing an Exclusive OR operation on AUX(X) and FF₂₄₈(X), the following equations can be obtained:
AUX(X)⊕FF₂₄₈(X)={FF₁₀₄(X), R(X)}⊕FF₂₄₈(X)={00₁₀₄(X), R′(X)}=R′(X)
→AUX(X)=R′(X)⊕FF₂₄₈(X)
→S(AUX(X))=S(R′(X))⊕S(FF₂₄₈(X))

where 00₁₀₄(X) represents 104 bytes of “00”, and S(AUX(X)) represents a syndrome value corresponding to AUX(X).

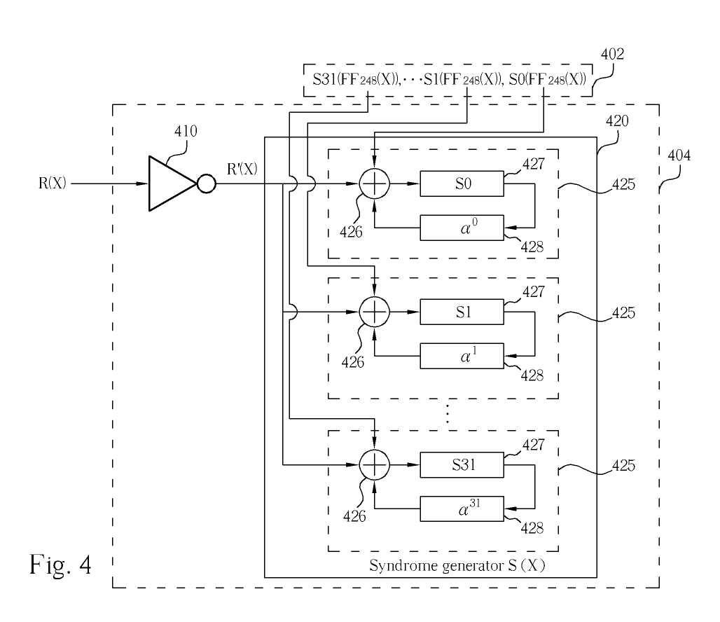

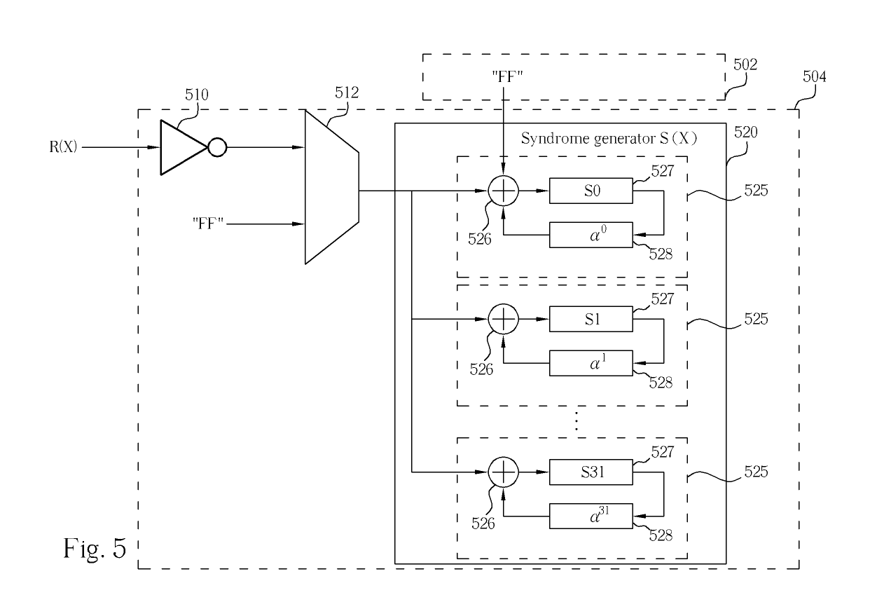

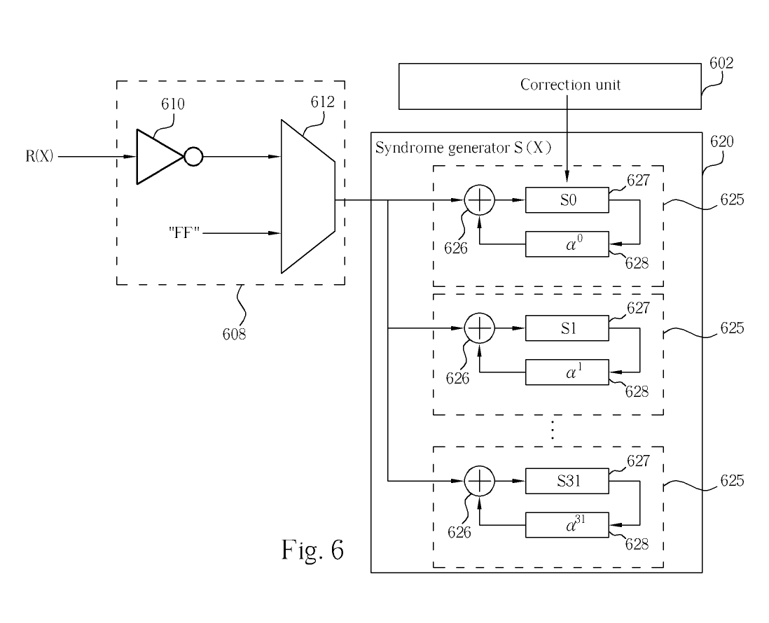

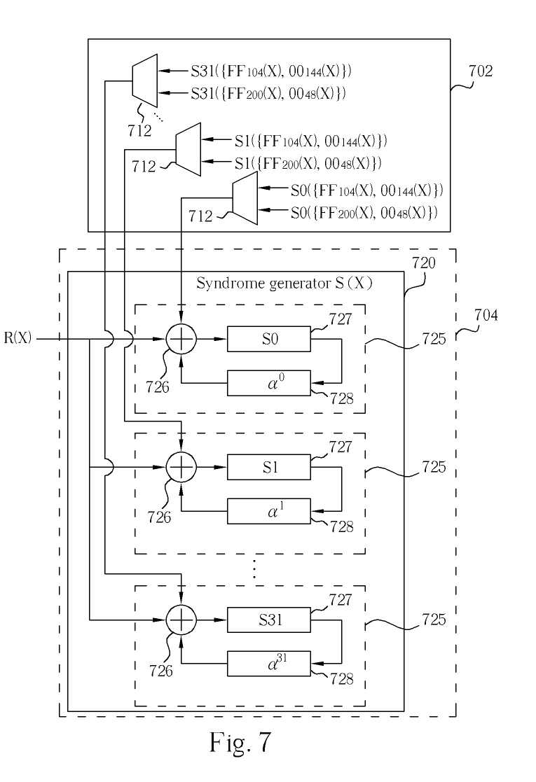

Therefore, when calculating the syndrome value S(BCA(X))/S(AUX(X)) corresponding to BCA(X)/AUX(X), a first syndrome value S(FF₂₄₈(X)) corresponding to a first preset ECC FF₂₄₈(X) can be provided as a fixed syndrome value. The first syndrome value S(FF₂₄₈(X)) comprises 32 syndrome bytes, which include S0(FF₂₄₈(X)), S1(FF₂₄₈(X)), . . . , S30(FF₂₄₈(X)), and S31(FF₂₄₈(X)). The syndrome value S(BCA(X))/S(AUX(X)) is then determined according to fixed syndrome value S(FF₂₄₈(X)) and R(X). FIG. 4 shows an apparatus according to a first embodiment, which allows a syndrome value to be generated more efficiently. The apparatus of this embodiment comprises a syndrome-providing module 402 and a calculator 404. The calculator 404 comprises an inverter 410 and a syndrome generator 420. The syndrome-providing module 402 provides a fixed syndrome value S(FF₂₄₈(X)); the inverter 410 inverts R(X) to generates a first modified section R′(X); and the syndrome generator 420 generates syndrome value S(BCA(X))/S(AUX(X)) according to the fixed syndrome value S(FF₂₄₈(X)) and first modified section R′(X).

In this embodiment, the syndrome generator 420 includes 32 syndrome byte generators 425, each of which is responsible for generating one syndrome byte of the syndrome value S(BCA(X))/S(AUX(X)). Each syndrome byte generator 425 includes an adder 426 for performing Exclusive OR operations, a buffer 427 for buffering a syndrome byte, and a multiplier 428. As the fixed syndrome value S(FF₂₄₈(X)) is determined in advance, the syndrome generator 420 can load the fixed syndrome value S(FF₂₄₈(X)) before/while/after loading the first modified section R′(X). Therefore, the number of clock cycles required when generating the syndrome value S(BCA(X)) or S(AUX(X)) is less than that required in the related art. The first embodiment therefore enables the syndrome values S(BCA(X)) and S(AUX(X)) to be generated more efficiently. Please note that if the fixed syndrome value is loaded into the syndrome generator 420 at a different time point, the actual content of the loaded fixed syndrome value should be properly revised.

A second embodiment is herein introduced. Taking BCA(X) as an example, if 7 bytes of “00” are added to the tail of BCA(X), BCA′(X), equaling {FF₂₀₀(X), R(X), 00₇(X)}, is generated. By performing Exclusive OR operations on BCA′(X) and FF₂₅₅(X), the following equations can be obtained:
BCA′(X)⊕FF₂₅₅(X)={00₂₀₀(X), R′(X), FF₇(X)}={R′(X), FF₇(X)}
→BCA′(X)={R′(X), FF₇(X)}⊕FF₂₅₅(X)
→S(BCA′(X))=S({R′(X), FF₇(X)})⊕S(FF₂₅₅(X))

Taking AUX(X) as an example, if 7 bytes of “00” are added to the tail of AUX(X), AUX′(X), equaling {FF₁₀₄(X), R(X), 00₇(X)}, is generated. By performing Exclusive OR operations on AUX′(X) and FF₂₅₅(X), the following equations can be obtained:
AUX′(X)⊕FF₂₅₅(X)={00₁₀₄(X), R′(X), FF₇(X)}={R′(X), FF₇(X)}
→AUX′(X)={R′(X), FF₇(X)}⊕FF₂₅₅(X)
→S(AUX′(X))=S({R′(X), FF₇(X)})⊕S(FF₂₅₅(X))

Therefore, when calculating the syndrome value S(BCA(X))/S(AUX(X)) corresponding to BCA(X)/AUX(X), a second syndrome value S(FF₂₅₅(X)) corresponding to a second preset ECC FF₂₅₅(X) can be provided as a fixed syndrome value. The syndrome value S(BCA(X))/S(AUX(X)) is then determined according to the fixed syndrome value S(FF₂₅₅(X)) and R(X). The second syndrome value S(FF₂₅₅(X)) includes 32 syndrome bytes, the first of which is “FF”, while the rest of which are all “00”.

FIG. 5 shows an apparatus according to the second embodiment, which allows syndrome values to be generated more efficiently. The apparatus of this embodiment comprises a syndrome-providing module 502 and a calculator 504. The calculator 504 comprises an inverter 510, a multiplexer 512, and a syndrome generator 520. The inverter 510 inverts R(X) to generates an inverted section R′(X); and the multiplexer adds the inverted section R′(X) with 7 bytes of “FF” to generate a second modified section {R′(X), FF₇(X)}. Since in the fixed syndrome value S(FF₂₅₅(X)) only the first syndrome byte is “FF” and other syndrome bytes are all “00”, the syndrome-providing module 502 in this embodiment only has to provide byte “FF”. The syndrome generator 520 then generates the syndrome value S(BCA′(X))/S(AUX′(X)) according to the fixed syndrome value S(FF₂₅₅(X)) and the second modified section {R′(X), FF₇(X)}.

In this embodiment, the syndrome generator 520 includes 32 syndrome byte generators 525, each of which is responsible for generating one syndrome byte of the syndrome value S(BCA′(X))/S(AUX′(X)). Each syndrome byte generator 525 includes an adder 526 for performing Exclusive OR operations, a buffer 527 for buffering a syndrome byte, and a multiplier 528. As the fixed syndrome value S(FF₂₅₅(X)) is determined beforehand, the syndrome generator 520 can load the fixed syndrome value S(FF₂₄₈(X)) before/while/after loading the second modified section R′(X). Therefore, the number of clock cycles required when generating the syndrome value S(BCA(X)) or S(AUX(X)) is less than that required in the related art. The second embodiment therefore enables the syndrome values S(BCA(X)) and S(AUX(X)) to be generated more efficiently.

Since performing Exclusive OR operations on any input byte and “FF” leads to the generation of the inverted byte of the input byte, the second embodiment shown in FIG. 5 can be modified to become the third embodiment shown in FIG. 6. The apparatus of the third embodiment comprises a revise module 608, a syndrome generator 620, and a correction unit 602. The revise module 608 comprises an inverter 610 and a multiplexer 612. The inverter 610 inverts R(X) to generate an inverted section R′(X); and the multiplexer 612 adds the inverted section R′(X) with 7 bytes “FF” to generate a second modified section {R′(X), FF₇(X)}. The syndrome generator 620 generates the syndrome value corresponding to the second modified section {R′(X), FF₇(X)}; and the correction unit 602 inverts the first syndrome byte of the syndrome value generated by the syndrome generator 620 to generate the syndrome value S(BCA′(X))/S(AUX′(X)).

A fourth embodiment is herein introduced. The following equations can be listed for BCA(X) and AUX(X):
S(BCA(X))=S({FF₂₀₀(X), R(X)})=S({FF₂₀₀(X), 00₄₈(X)})⊕S(R(X))
S(AUX(X))=S({FF₁₀₄(X), R(X)})=S({FF₁₀₄(X), 00₁₄₄(X)})⊕S(R(X))

Therefore, when calculating the syndrome value S(BCA(X)) corresponding to BCA(X), a third syndrome value S({FF₂₀₀(X), 00₄₈(X)}) corresponding to a third preset ECC {FF₂₀₀(X), 00₄₈(X)} can be provided as a fixed syndrome value. The syndrome value S(BCA(X)) is then determined according to the fixed syndrome value S({FF₂₀₀(X), 00₄₈(X)}) and R(X). When calculating the syndrome value S(AUX(X)) corresponding to AUX(X), a fourth syndrome value S({FF₁₀₄(X), 00₁₄₄(X)}) corresponding to a fourth preset ECC {FF₁₀₄(X), 00₁₄₄(X)} can be provided as a fixed syndrome value. The syndrome value S(AUX(X)) is then determined according to the fixed syndrome value S({FF₁₀₄(X), 00₁₄₄(X)}) and R(X). FIG. 7 shows an apparatus, which allows syndrome values to be generated more efficiently, according to a fourth embodiment. The apparatus of this embodiment comprises a syndrome-providing module 702 and a calculator 704. The syndrome-providing module 702 comprises 32 multiplexers 712. Each of the multiplexer 712 provides one syndrome byte of the fixed syndrome value S({FF₂₀₀(X), 00₄₈(X)})/S({FF₁₀₄(X), 00₁₄₄(X)}). The calculator 704 comprises a syndrome generator 720. The syndrome generator 720 generates the syndrome value S(BCA(X))/S(AUX(X)) according to the fixed syndrome value S({FF₂₀₀(X), 00₄₈(X)})/S({FF₁₀₄(X), 00₁₄₄(X)}) and R(X).

In this embodiment, the syndrome generator 720 includes 32 syndrome byte generators 725, each of which is responsible for generating one syndrome byte of the syndrome value S(BCA(X))/S(AUX(X)). Each syndrome byte generator 725 includes an adder 726 for performing Exclusive OR operations, a buffer 727 for buffering a syndrome byte, and a multiplier 728. As the fixed syndrome value S({FF₂₀₀(X), 00₄₈(X)})/S({FF₁₀₄(X), 00₁₄₄(X)}) is determined beforehand, the syndrome generator 720 can load the fixed syndrome value S({FF₂₀₀(X), 00₄₈(X)})/S({FF₁₀₄(X), 00₁₄₄(X)}) before/while/after loading R(X). Therefore, the number of clock cycles required when generating the syndrome value S(BCA(X))/S(AUX(X)) is less than that required in the related art. The fourth embodiment therefore enables the syndrome values S(BCA(X)) and S(AUX(X)) to be generated more efficiently. Please note that if the fixed syndrome value is loaded into the syndrome generator 720 at a different time point, the actual content of the fixed syndrome value should be properly revised. Taking BCA(X) as an example, if the fixed syndrome value is loaded into the syndrome generator 720 before R(X) is loaded, S({FF₂₀₀(X)} should be provided as the fixed syndrome value. If the fixed syndrome value is loaded into the syndrome generator 720 while the first byte of R(X) is loaded, S({FF₂₀₀(X), 00₁(X)} should be provided as the fixed syndrome value.

What is claimed is:

1. A method for generating a syndrome value corresponding to an error correction codeword (ECC), the ECC comprising a fixed section, an information section, and a parity section, the fixed section including not only byte “00”, the method comprising:
providing a fixed syndrome value according to characteristics of the ECC; and
generating the syndrome value corresponding to the ECC according to the fixed syndrome value, the information section, and the parity section.

2. The method of claim 1, wherein the ECC is a Reed-Solomon codeword.

3. The method of claim 2, wherein the characteristics of the ECC comprise:
the fixed section comprising 200 bytes of “FF”;
the information section comprising 16 information bytes; and
the parity section comprising 32 parity bytes.

4. The method of claim 3, wherein the step of generating the syndrome value corresponding to the ECC comprises:
inverting the information section and the parity section to generate a first modified section; and
generating the syndrome value corresponding to the ECC according to the fixed syndrome value and the first modified section;
wherein the fixed syndrome value corresponds to a first preset ECC, which comprises 248 bytes of “FF”.

5. The method of claim 3, wherein the step of generating the syndrome value corresponding to the ECC comprises:
inverting the information section and the parity section;
adding the inverted section of the information section and the parity section with 7 bytes of “FF” to generate a second modified section; and
generating the syndrome value corresponding to the ECC according to the fixed syndrome value and the second modified section;
wherein the fixed syndrome value corresponds to a second preset ECC, which comprises 255 bytes of “FF”.

6. he method of claim 3, wherein the fixed syndrome value corresponds to a third preset ECC, which comprises 200 bytes of “FF” and 48 bytes of “00”.

7. The method of claim 2, wherein the characteristics of the ECC comprise:
the fixed section comprising 104 bytes of “FF”;
the information section comprising 112 information bytes; and
the parity section comprising 32 parity bytes.

8. The method of claim 7, wherein the step of generating the syndrome value corresponding to the ECC comprises:
inverting the information section and the parity section to generate a first modified section; and
generating the syndrome value corresponding to the ECC according to the fixed syndrome value and the first modified section;
wherein the fixed syndrome value corresponds to a first preset ECC, which comprises 248 bytes of “FF”.

9. The method of claim 7, wherein the step of generating the syndrome value corresponding to the ECC comprises:
inverting the information section and the parity section;
adding the inverted section of the information section and the parity section with 7 bytes of “FF” to generate a second modified section; and
generating the syndrome value corresponding to the ECC according to the fixed syndrome value and the second modified section;
wherein the fixed syndrome value corresponds to a second preset ECC, which comprises 255 bytes of “FF”.

10. The method of claim 7, wherein the fixed syndrome value corresponds to a fourth preset ECC, which comprises 104 bytes of “FF” and 144 bytes of “00”.

11. An apparatus for generating a syndrome value corresponding to an error correction codeword (ECC), the ECC comprising a fixed section, an information section, and a parity section, the fixed section including not only byte “00”, the apparatus comprising:
a syndrome-providing module, for providing a fixed syndrome value according to characteristics of the ECC; and
a calculator, coupled to the syndrome-providing module, for generating the syndrome value corresponding to the ECC according to the fixed syndrome value, the information section, and the parity section.

12. The apparatus of claim 11, wherein the ECC is a Reed-Solomon codeword.

13. The apparatus of claim 12, wherein the characteristics of the ECC comprise:
the fixed section comprising 200 bytes of “FF”;
the information section comprising 16 information bytes; and
the parity section comprising 32 parity bytes.

14. The apparatus of claim 13, wherein the calculator comprises:
an inverter, for inverting the information section and the parity section to generate a first modified section; and
a syndrome generator, coupled to the inverter and the syndrome-providing module, for generating the syndrome value corresponding to the ECC according to the fixed syndrome value and the first modified section;
wherein the fixed syndrome value corresponds to a first preset ECC, which comprises 248 bytes of “FF”.

15. The apparatus of claim 13, wherein the calculator comprises:
a modifier, for inverting the information section and the parity section, and adding the inverted section of the information section and the parity section with 7 bytes of “FF” to generate a second modified section; and
a syndrome generator, coupled to the modifier and the syndrome-providing module, for generating the syndrome value corresponding to the ECC according to the fixed syndrome value and the second modified section;
wherein the fixed syndrome value corresponds to a second preset ECC, which comprises 255 bytes of “FF”.

16. The apparatus of claim 13, wherein the fixed syndrome value corresponds to a third preset ECC, which comprises 200 bytes of “FF” and 48 bytes of “00”.

17. The apparatus of claim 12, wherein the characteristics of the ECC comprise:
the fixed section comprising 104 bytes of “FF”;
the information section comprising 112 information bytes; and
the parity section comprising 32 parity bytes.

18. The apparatus of claim 17, wherein the calculator comprises:
an inverter, for inverting the information section and the parity section to generate a first modified section; and
a syndrome generator, coupled to the inverter and the syndrome-providing module, for generating the syndrome value corresponding to the ECC according to the fixed syndrome value and the first modified section;
wherein the fixed syndrome value corresponds to a first preset ECC, which comprises 248 bytes of “FF”.

19. The apparatus of claim 17, wherein the calculator comprises:
a modifier, for inverting the information section and the parity section, and adding the inverted section of the information section and the parity section with 7 bytes of “FF” to generate a second modified section; and
a syndrome generator, coupled to the modifier and the syndrome-providing module, for generating the syndrome value corresponding to the ECC according to the fixed syndrome value and the second modified section;
wherein the fixed syndrome value corresponds to a second preset ECC, which comprises 255 bytes of “FF”.

20. The apparatus of claim 17, wherein the fixed syndrome value corresponds to a fourth preset ECC, which comprises 104 bytes of “FF” and 144 bytes of “00”.

21. A method for generating a syndrome value corresponding to an error correction codeword (ECC), the ECC comprising a fixed section, an information section, and a parity section, the fixed section including not only byte “00”, the method comprising:
generating a second modified section according to the information section, the parity section, and a preset section;
generating a syndrome value corresponding to the second modified section; and
modifying the syndrome value corresponding to the second modified section according to characteristics of the ECC to generate the syndrome value corresponding to the ECC.

22. The method of claim 21, wherein the ECC is a Reed-Solomon codeword.

23. The method of claim 22, wherein:
the step of generating the second modified section comprises:
inverting the information section and the parity section; and
adding the inverted section of the information section and the parity section with the preset section to generate the second modified section; and
the step of generating the syndrome value corresponding to the ECC comprises:
inverting a k^{th} syndrome byte of the syndrome value corresponding to the second modified section to generate the syndrome value corresponding to the ECC.

24. The method of claim 23, wherein the preset section comprises 7 bytes of “FF”, and the characteristics of the ECC comprise:
the fixed section comprising 200 bytes of “FF”;
the information section comprising 16 information bytes; and
the parity section comprising 32 parity bytes.

25. The method of claim 23, wherein the preset section comprises 7 bytes of “FF”, and the characteristics of the ECC comprise:
the fixed section comprising 104 bytes of “FF”;
the information section comprising 112 information bytes; and
the parity section comprising 32 parity bytes.

26. An apparatus for generating a syndrome value corresponding to an error correction codeword (ECC), the ECC comprising a fixed section, an information section, and a parity section, the fixed section including not only byte “00”, the apparatus comprising:
a revise module, for generating a second modified section according to the information section, the parity section, and a preset section;
a syndrome generator, coupled to the revise module, for generating a syndrome value corresponding to the second modified section; and
a correction unit, coupled to the syndrome generator, for inverting a k^{th} syndrome byte of the syndrome value corresponding the second modified section to generate the syndrome value corresponding to the ECC.

27. The apparatus of claim 26, wherein the ECC is a Reed-Solomon codeword.

28. The apparatus of claim 27, wherein the revise module inverts the information section and the parity section, and adds the inverted section of the information section and the parity section with the preset section to generate the second modified section.

29. The apparatus of claim 28, wherein the preset section comprises 7 bytes of “FF”, and the characteristics of the ECC comprise:
the fixed section comprising 200 bytes of “FF”;
the information section comprising 16 information bytes; and
the parity section comprising 32 parity bytes.

30. The apparatus of claim 28, wherein the preset section comprises 7 bytes of “FF”, and the characteristics of the ECC comprise:
the fixed section comprising 104 bytes of “FF”;
the information section comprising 112 information bytes; and
the parity section comprising 32 parity bytes.
